(19) United States
(12) Patent Application Publication
(10) Pub. No.: US 2025/0372025 A1
(43) Pub. Date: Dec. 4, 2025

(54) DISPLAY DEVICE AND ELECTRONIC APPARATUS INCLUDING THE SAME

(71) Applicant: Samsung Display Co., LTD., Yongin-si (KR)

(72) Inventors: KEUNWOO KIM, Yongin-si (KR); SOYOUNG KOO, Yongin-si (KR); JONGDO KEUM, Yongin-si (KR); BUMMO SUNG, Yongin-si (KR); HYELIM CHOI, Yongin-si (KR)

(73) Assignee: Samsung Display Co., LTD., Yongin-si (KR)

(21) Appl. No.: 19/061,343

(22) Filed: Feb. 24, 2025

(30) Foreign Application Priority Data
May 29, 2024 (KR) 10-2024-0069731

(51) Int. Cl. G09G 3/32; H10D 86/40

(52) U.S. Cl. CPC G09G 3/32; G09G 2300/0819; G09G 2300/0852; G09G 2300/0861; G09G 2310/08; G09G 2330/021; H10D 86/423; H10D 86/451

(57) ABSTRACT

A display device includes a pixel. The pixel includes a light-emitting element, a first transistor which controls a driving current flowing through the light-emitting element, and including a gate connected to a first node, a first electrode connected to a second node, and a second electrode connected to a third node, a second transistor which transmits a data voltage to a fourth node in response to a first gate signal, a storage capacitor connected between the first node and the fourth node, and an emission control transistor which transmits a first power voltage to the second node in response to a second gate signal or a first emission signal, including a first gate which receives the first emission signal and a second gate which receives the second gate signal, and being an oxide n-channel metal oxide semiconductor (NMOS) transistor.

### CROSS-REFERENCE TO RELATED APPLICATION(S)

This application claims priority to and benefits Korean Patent Application No. 10-2024-0069731 under 35 USC § 119, filed on May 29, 2024, in the Korean Intellectual Property Office (KIPO), the entire contents of which are incorporated herein by reference.

### BACKGROUND

### 1. Technical Field

Embodiments relate to a display device.

### 2. Description of the Related Art

A display device may include a display panel including pixels, a gate driver providing gate signals to the pixels, and a data driver providing data voltages to the pixels. In case that the number of gate signals provided to each pixel increases, power consumption and an area of the gate driver may increase, and thus, power consumption and a dead space of the display device may increase.

The display device may include a demultiplexer selectively and electrically connecting data lines to a channel of the data driver based on selection signals. In case that the number of selection signals increases, power consumption and an area of the demultiplexer may increase, and thus, power consumption and a dead space of the display device may increase.

### SUMMARY

Embodiments provide a display device in which power consumption and a dead space are reduced, and an electronic apparatus including the display device.

However, embodiments are not limited to those set forth herein. The above and other embodiments will become more apparent to one of ordinary skill in the art to which the disclosure pertains by referencing the detailed description of the disclosure given below.

In an embodiment, a display device may include a pixel including a light-emitting element, a first transistor which controls a driving current flowing through the light-emitting element, and including a gate connected to a first node, a first electrode connected to a second node, and a second electrode connected to a third node, a second transistor which transmits a data voltage to a fourth node in response to a first gate signal, a storage capacitor connected between the first node and the fourth node, and an emission control transistor which transmits a first power voltage to the second node in response to a second gate signal or a first emission signal, including a first gate which receives the first emission signal and a second gate which receives the second gate signal, and being an oxide n-channel metal oxide semiconductor (NMOS) transistor.

In an embodiment, the pixel may further include a third transistor which connects the first node and the third node in response to the second gate signal, a fourth transistor which transmits a first initialization voltage to the first node in response to a third gate signal, and a fifth transistor which transmits a reference voltage to the fourth node in response to the second gate signal.

In an embodiment, in a compensation period, the emission control transistor may be turned-on in response to the second gate signal having an activation level, and the first power voltage for which a threshold voltage of the first transistor is compensated may be applied to the first node through the emission control transistor, the first transistor, and the third transistor.

In an embodiment, the pixel may further include a sixth transistor which connects the third node and an anode of the light-emitting element in response to the first emission signal, and a seventh transistor which transmits a second initialization voltage to the anode of the light-emitting element in response to a second emission signal.

In an embodiment, in an emission period, the emission control transistor may be turned-on in response to the first emission signal having an activation level, and a path of the driving current may be formed through the emission control transistor, the first transistor, and the sixth transistor.

In an embodiment, each of the first to seventh transistors may be an oxide NMOS transistor.

In an embodiment, the pixel may further include a hold capacitor including a first electrode connected to the fourth node and a second electrode which receives the first power voltage.

In an embodiment, the pixel may further include a bias control transistor which provides a bias voltage to the second node in response to the second emission signal.

In an embodiment, the first transistor may be a polysilicon p-channel metal oxide semiconductor (PMOS) transistor, and each of the second to sixth transistors may be an oxide NMOS transistor.

In an embodiment, each of the seventh transistor and the bias control transistor may be a polysilicon PMOS transistor.

A display device according to embodiments may include a substrate, a first gate electrode disposed on the substrate, a first insulation layer disposed on the first gate electrode, an active layer disposed on the first insulation layer, overlapping the first gate electrode, and including an oxide semiconductor, a second insulation layer disposed on the active layer, and a second gate electrode disposed on the second insulation layer and overlapping the active layer. A thickness ratio of the first insulation layer and the second insulation layer may be less than 2:1.

In an embodiment, a thickness of the first insulation layer may be greater than a thickness of the second insulation layer and less than twice the thickness of the second insulation layer.

In an embodiment, in case that a signal having an activation level is applied to the first gate electrode and a signal having a deactivation level is applied to the second gate electrode, a first channel may be formed in a direction from a drain of the active layer toward a source of the active layer in a portion of the active layer adjacent to the first insulation layer.

In an embodiment, in case that a signal having an activation level is applied to the second gate electrode and a signal having a deactivation level is applied to the first gate electrode, a second channel may be formed in a direction from the drain toward the source in a portion of the active layer adjacent to the second insulation layer.

In an embodiment, the active layer may include at least one oxide semiconductor of indium gallium zinc oxide (IGZO), indium tin gallium zinc oxide (ITGZO), and indium gallium oxide (IGO).

In an embodiment, an electronic apparatus may include a display device including a pixel and a processor which controls the display device according to embodiments, the pixel may include a light-emitting element, a first transistor which controls a driving current flowing through the light-emitting element and including a gate connected to a first node, a first electrode connected to a second node, and a second electrode connected to a third node, a second transistor which transmits a data voltage to a fourth node in response to a first gate signal, a storage capacitor connected between the first node and the fourth node, and an emission control transistor which transmits a first power voltage to the second node in response to a second gate signal or a first emission signal, including a first gate which receives the first emission signal and a second gate which receives the second gate signal, and being an oxide NMOS transistor.

The electronic apparatus may further include: a third transistor which connects the first node and the third node in response to the second gate signal; a fourth transistor which transmits a first initialization voltage to the first node in response to a third gate signal; and a fifth transistor which transmits a reference voltage to the fourth node in response to the second gate signal.

In a compensation period, the emission control transistor may be turned-on in response to the second gate signal having an activation level, and the first power voltage for which a threshold voltage of the first transistor is compensated may be applied to the first node through the emission control transistor, the first transistor, and the third transistor.

The pixel may further include: a sixth transistor which connects the third node and an anode of the light-emitting element in response to the first emission signal; and a seventh transistor which transmits a second initialization voltage to the anode of the light-emitting element in response to a second emission signal.

In an emission period, the emission control transistor may be turned-on in response to the first emission signal having an activation level, and a path of the driving current may be formed through the emission control transistor, the first transistor, and the sixth transistor.

In the display device and the electronic apparatus according to the embodiments, the emission control transistor of the pixel may be turned-on in response to the second gate signal or the first emission signal, and thus, the number of signals provided to the pixel may be reduced, and the power consumption and the dead space of the display device may be reduced. Further, the first and second selection transistors of the demultiplexer may be turned-on in response to the selection signal, and thus, the number of selection signals may be reduced, and the power consumption and the dead space of the display device may be reduced.

### BRIEF DESCRIPTION OF THE DRAWINGS

Illustrative, non-limiting embodiments will be more clearly understood from the following detailed description taken in conjunction with the accompanying drawings.

FIG. 1 is a schematic block diagram showing a display device according to an embodiment.

FIG. 2 is a schematic diagram of an equivalent circuit of an example of a pixel of FIG. 1.

FIG. 3 is a timing diagram showing gate signals and emission signals provided to the pixel of FIG. 2.

FIGS. 4 to 8 are schematic views for describing an operation of the pixel of FIG. 2.

FIG. 9 is a schematic diagram of an equivalent circuit of an example of a pixel of FIG. 1.

FIG. 10 is a schematic cross-sectional view showing an eighth transistor of FIGS. 2 and 9.

FIGS. 11 and 12 are schematic views for describing an operation of the eighth transistor of FIG. 10.

FIG. 13 is a schematic block diagram showing a display device according to an embodiment.

FIG. 14 is a schematic diagram of an equivalent circuit of an example of a demultiplexer of FIG. 13.

FIG. 15 is a timing diagram showing a selection signal provided to the demultiplexer of FIG. 14.

FIG. 16 is a schematic block diagram showing an electronic apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction D1, the axis of the second direction D2, and the axis of the third direction D3 are not limited to three axes of a rectangular coordinate system, such as the X, Y, and Z-axes, and may be interpreted in a broader sense. For example, the axis of the first direction D1, the axis of the second direction D2, and the axis of the third direction D3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

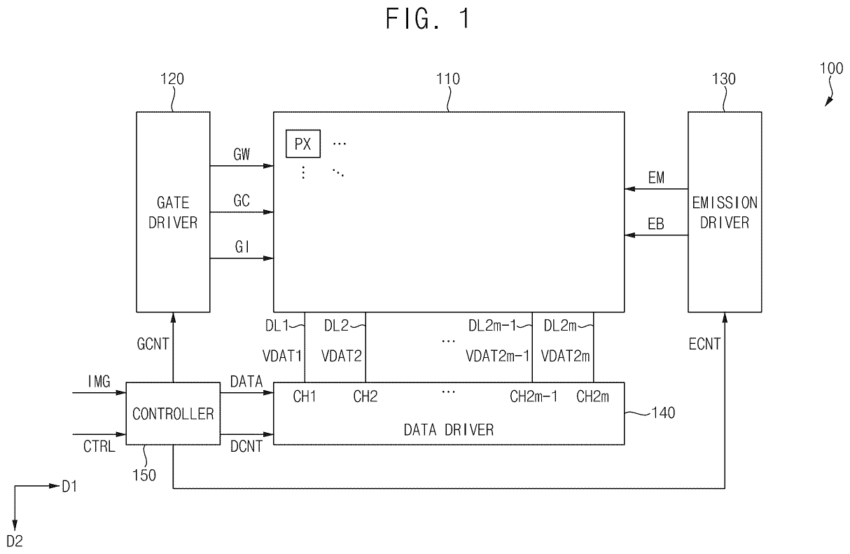

FIG. 1 is a schematic block diagram showing a display device 100 according to an embodiment.

Referring to FIG. 1, a display device 100 may include a display panel 110, a gate driver 120, an emission driver 130, a data driver 140, and a controller 150.

The display panel 110 may include pixels PX, gate lines, emission lines, and data lines DL1, DL2, . . . , DL2m-1, and DL2m (m is a natural number greater than or equal to 2). The pixels PX may be connected to the gate lines, the emission lines, and the data lines DL1, DL2, . . . , DL2m-1, and DL2m.

The gate lines may extend in a first direction D1, and may be arranged in a second direction D2 intersecting the first direction D1. The gate lines may transmit gate signals GW, GC, and GI. The gate signals GW, GC, and GI may include a first gate signal GW, a second gate signal GC, and a third gate signal GI.

The emission lines may extend in the first direction D1, and may be arranged in the second direction D2. The emission lines may transmit emission signals EM and EB. The emission signals EM and EB may include a first emission signal EM and a second emission signal EB.

The data lines DL1, DL2, . . . , DL2m-1, and DL2m may extend in the second direction D2, and may be arranged in the first direction D1. The data lines DL1, DL2, . . . , DL2m-1, and DL2m may transmit data voltages VDAT1, VDAT2, . . . , VDAT2m-1, and VDAT2m.

The gate driver 120 may output the gate signals GW, GC, and GI to the gate lines. The gate driver 120 may generate the gate signals GW, GC, and GI based on a gate control signal GCNT. The gate control signal GCNT may include a gate clock signal, a gate start signal, etc.

The emission driver 130 may output the emission signals EM and EB to the emission lines. The emission driver 130 may generate emission signals EM and EB based on an emission control signal ECNT. The emission control signal ECNT may include an emission clock signal, an emission start signal, etc.

The data driver 140 may output the data voltages VDAT1, VDAT2, . . . , VDAT2m-1, and VDAT2m to the data lines DL1, DL2, . . . , DL2m-1, and DL2m. The data driver 140 may generate the data voltages VDAT1, VDAT2, . . . , VDAT2m-1, and VDAT2m based on a data signal DATA and a data control signal DCNT. The data driver 140 may convert the digital data signal DATA into the analog data voltages VDAT1, VDAT2, . . . , VDAT2m-1, and VDAT2m. The data control signal DCNT may include a data clock signal, a load signal, etc.

The data driver 140 may include channels CH1, CH2, . . . , CH2m-1, and CH2m that provide the data voltages VDAT1, VDAT2, . . . , VDAT2m-1, and VDAT2m to the data lines DL1, DL2, . . . , DL2m-1, and DL2m, respectively. The number of channels CH1, CH2, . . . , CH2m-1, and CH2m may be equal to the number of data lines DL1, DL2, . . . , DL2m-1, and DL2m.

The controller 150 may control an operation of the gate driver 120, an operation of the emission driver 130, and an operation of the data driver 140. The controller 150 may provide the gate control signal GCNT to the gate driver 120, the emission control signal ECNT to the emission driver 130, and the data signal DATA and the data control signal DCNT to the data driver 140. The controller 150 may generate the gate control signal GCNT, the emission control signal ECNT, the data signal DATA, and the data control signal DCNT based on image data IMG and a controller control signal CTRL. The image data IMG may include grayscales corresponding to pixels PX. The controller control signal CTRL may include a master clock signal, a vertical sync signal, a horizontal sync signal, a data enable signal, etc.

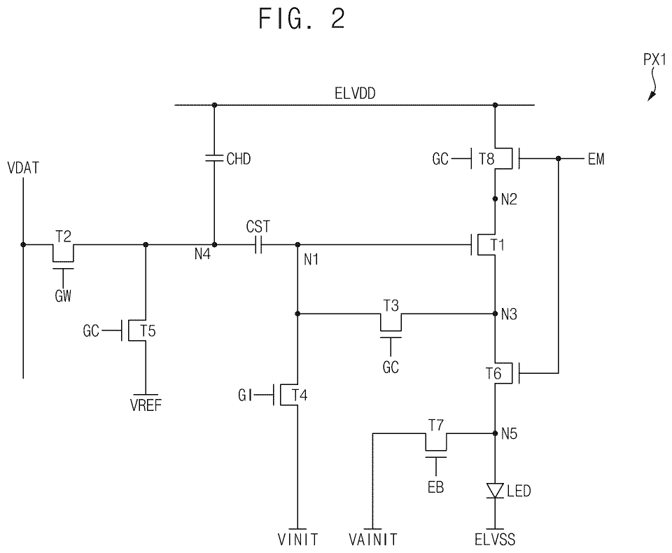

FIG. 2 is a schematic diagram of an equivalent circuit of an example of the pixel PX1 of FIG. 1.

Referring to FIG. 2, the pixel PX1 may receive the first gate signal GW, the second gate signal GC, the third gate signal GI, the first emission signal EM, the second emission signal EB, the data voltage VDAT, a first initialization voltage VINIT, a second initialization voltage VAINIT, a reference voltage VREF, a first power voltage ELVDD, and a second power voltage ELVSS. The pixel PX1 may include a light-emitting element LED, a first transistor T1, a second transistor T2, a third transistor T3, a fourth transistor T4, a fifth transistor T5, a sixth transistor T6, a seventh transistor T7, an eighth transistor T8, a storage capacitor CST, and a hold capacitor CHD.

The light-emitting element LED may emit light with a luminance corresponding to a driving current. The light-emitting element LED may include an anode connected to a fifth node N5 and a cathode receiving the second power voltage ELVSS.

The first transistor T1 may control the driving current flowing through the light-emitting element LED. The first transistor T1 may include a gate connected to a first node N1, a first electrode connected to a second node N2, and a second electrode connected to a third node N3.

The second transistor T2 may transmit the data voltage VDAT to the fourth node N4 in response to the first gate signal GW. The second transistor T2 may include a gate receiving the first gate signal GW, a first electrode receiving the data voltage VDAT, and a second electrode connected to the fourth node N4.

The third transistor T3 may connect the first node N1 and the third node N3 in response to the second gate signal GC. The third transistor T3 may include a gate receiving the second gate signal GC, a first electrode connected to the third node N3, and a second electrode connected to the first node N1.

The fourth transistor T4 may transmit the first initialization voltage VINIT to the first node N1 in response to the third gate signal GI. The fourth transistor T4 may include a gate receiving the third gate signal GI, a first electrode receiving the first initialization voltage VINIT, and a second electrode connected to the first node N1.

The fifth transistor T5 may transmit the reference voltage VREF to the fourth node N4 in response to the second gate signal GC. The fifth transistor T5 may include a gate receiving the second gate signal GC, a first electrode receiving the reference voltage VREF, and a second electrode connected to the fourth node N4.

The sixth transistor T6 may connect the third node N3 and the fifth node N5 in response to the first emission signal EM. The sixth transistor T6 may include a gate receiving the first emission signal EM, a first electrode connected to the third node N3, and a second electrode connected to the fifth node N5.

The seventh transistor T7 may transmit the second initialization voltage VAINIT to the fifth node N5 in response to the second emission signal EB. The seventh transistor T7 may include a gate receiving the second emission signal EB, a first electrode receiving the second initialization voltage VAINIT, and a second electrode connected to the fifth node N5.

In an embodiment, each of the first to seventh transistors T1, T2, T3, T4, T5, T6, and T7 may be an oxide n-channel metal oxide semiconductor (NMOS) transistor. The oxide NMOS transistor may be an NMOS transistor including an oxide semiconductor. However, embodiments are not limited thereto, and in another embodiment, at least one of the first to seventh transistors T1, T2, T3, T4, T5, T6, and T7 may be a polysilicon p-channel metal oxide semiconductor (PMOS) transistor. The polysilicon PMOS transistor may be a PMOS transistor including a polysilicon semiconductor.

The eighth transistor T8 may transmit the first power voltage ELVDD to the second node N2 in response to the second gate signal GC or the first emission signal EM. The eighth transistor T8 may include a first gate receiving the first emission signal EM, a second gate receiving the second gate signal GC, a first electrode receiving the first power voltage ELVDD, and a second electrode connected to the second node N2. The eighth transistor T8 may be an oxide NMOS transistor.

The eighth transistor (e.g., emission control transistor) T8 may be turned-on in response to a signal applied to the first gate or a signal applied to the second gate. For example, the eighth transistor T8 may be turned-on in case that the first emission signal EM having an activation level is applied to the first gate or in case that the second gate signal GC having an activation level is applied to the second gate.

The storage capacitor CST may store a signal of the first node N1, and may transmit a signal change of the fourth node N4 to the first node N1 by using a coupling effect. The storage capacitor CST may be connected between the first node N1 and the fourth node N4.

The hold capacitor CHD may store a signal of the fourth node N4. The hold capacitor CHD may include a first electrode connected to the fourth node N4 and a second electrode receiving the first power voltage ELVDD.

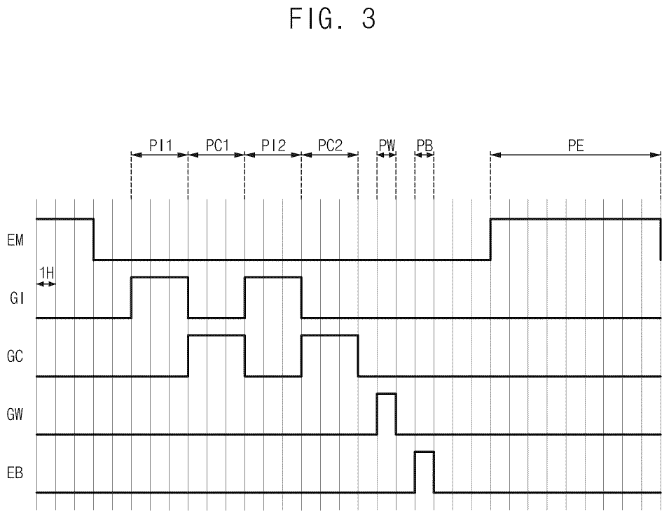

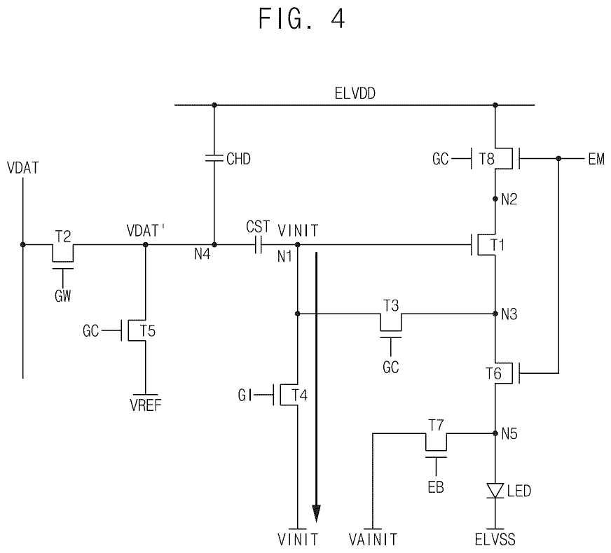

FIG. 3 is a timing diagram showing the gate signals GW, GC, and GI and the emission signals EM and EB provided to the pixel PX1 of FIG. 2. FIGS. 4 to 8 are schematic views for describing an operation of the pixel PX1 of FIG. 2.

Referring to FIGS. 3 and 4, in a first initialization period PI1, the fourth transistor T4 may be turned-on in response to the third gate signal GI having an activation level, and the first initialization voltage VINIT may be applied to the first node N1 through the fourth transistor T4. Accordingly, charges stored in the first node N1 may be discharged to a line transmitting the first initialization voltage VINIT, and the first transistor T1 may be turned-on.

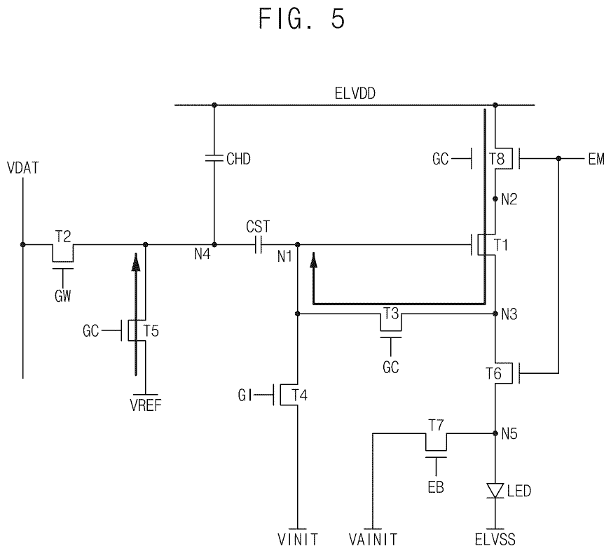

Referring to FIGS. 3 and 5, in a first compensation period PC1, the eighth transistor T8 and the third transistor T3 may be turned-on in response to the second gate signal G2 having an activation level, and the first power voltage ELVDD for which the threshold voltage of the first transistor T1 is compensated may be applied to the first node N1 through the eighth transistor T8, the first transistor T1, and the third transistor T3. The first power voltage ELVDD for which the threshold voltage of the first transistor T1 is compensated may correspond to a value obtained by subtracting the threshold voltage of the first transistor T1 from the first power voltage ELVDD. Further, the fifth transistor T5 may be turned-on in response to the second gate signal GC having the activation level, and the reference voltage VREF may be applied to the fourth node N4 through the fifth transistor T5. In the first initialization period PI1, the previous data voltage may be stored in the fourth node N4, and a voltage difference between the reference voltage VREF and the previous data voltage may be transmitted to the first node N1 by the coupling effect of the storage capacitor CST. Accordingly, a value obtained by adding the voltage difference between the reference voltage VREF and the previous data voltage to the first power voltage ELVDD for which the threshold voltage of the first transistor T1 is compensated may be stored in the first node N1.

Referring again to FIGS. 3 and 4, in a second initialization period PI2, the fourth transistor T4 may be turned-on in response to the third gate signal GI having the activation level, and the first initialization voltage VINIT may be applied to the first node N1 through the fourth transistor T4. Accordingly, charges stored in the first node N1 may be discharged to the line transmitting the first initialization voltage VINIT, and the first transistor T1 may be turned-on.

Referring again to FIGS. 3 and 5, in a second compensation period PC2, the eighth transistor T8 and the third transistor T3 may be turned-on in response to the second gate signal G2 having the activation level, and the first power voltage ELVDD for which the threshold voltage of the first transistor T1 is compensated may be applied to the first node N1 through the eighth transistor T8, the first transistor T1, and the third transistor T3. Further, the fifth transistor T5 may be turned-on in response to the second gate signal GC having the activation level, and the reference voltage VREF may be applied to the fourth node N4 through the fifth transistor T5. In the second initialization period PI2, the reference voltage VREF may be stored in the fourth node N4, and the signal of the fourth node N4 may not change. Accordingly, the first power voltage ELVDD for which the threshold voltage of the first transistor T1 is compensated may be stored in the first node N1.

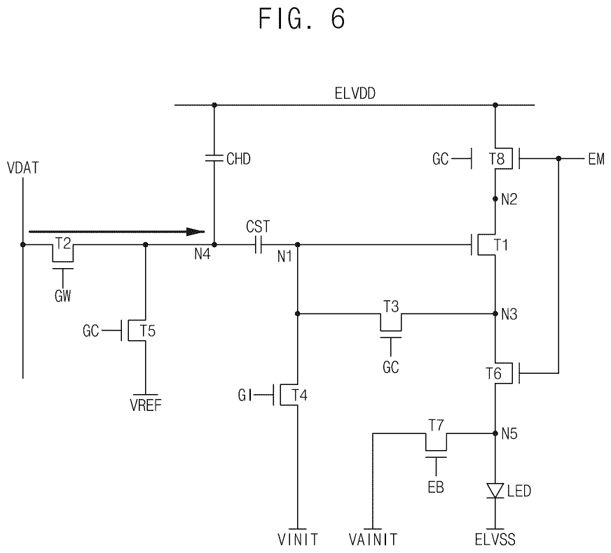

Referring to FIGS. 3 and 6, in a data writing period PW, the second transistor T2 may be turned-on in response to the first gate signal GW having an activation level, and the data voltage VDAT may be applied to the fourth node N4 through the second transistor T2. In the second initialization period PI2, the reference voltage REF may be stored in the fourth node N4, and a voltage difference between the data voltage VDAT and the reference voltage VREF may be transmitted to the first node N1 by the coupling effect of the storage capacitor CST. Accordingly, a value obtained by adding the voltage difference between the data voltage VDAT and the reference voltage VREF to the first power voltage ELVDD for which the threshold voltage of the first transistor T1 is compensated may be stored in the first node N1.

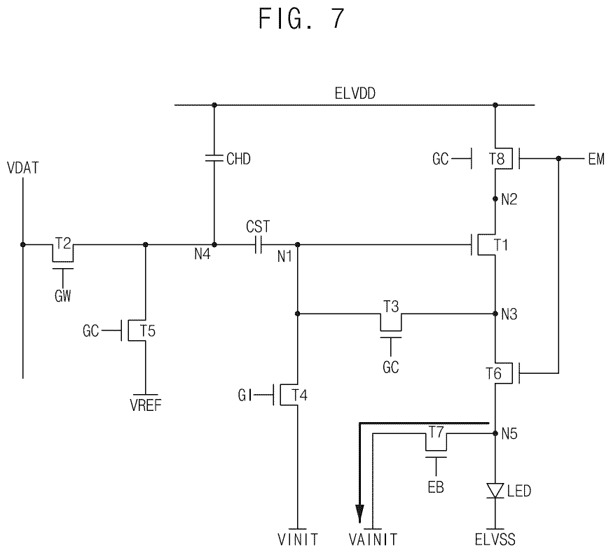

Referring to FIGS. 3 and 7, in a bypass period PB, the seventh transistor T7 may be turned-on in response to the second emission signal EB having an activation level, and the second initialization voltage VAINIT may be applied to the fifth node N5 through the seventh transistor T7. Accordingly, charges stored in the fifth node N5 may be discharged to a line transmitting the second initialization voltage VAINIT, and the light-emitting element LED may be initialized.

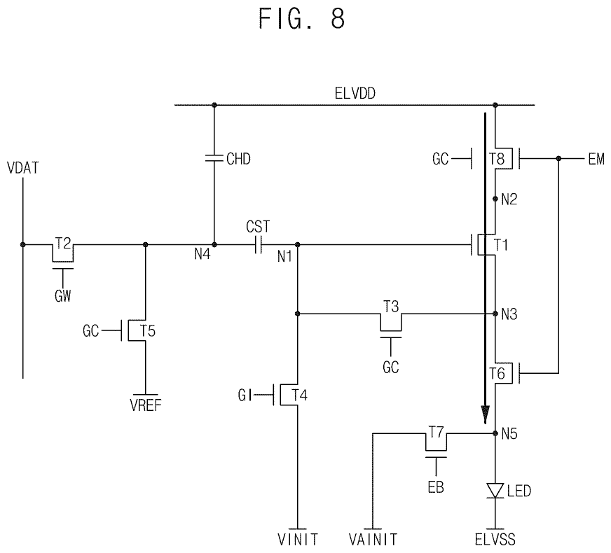

Referring to FIGS. 3 and 8, in an emission period PE, the eighth transistor T8 and the sixth transistor T6 may be turned-on in response to the first emission signal EM having an activation level, and a path of the driving current may be formed through the eighth transistor T8, the first transistor T1, and the sixth transistor T6. The driving current may correspond to a value obtained by subtracting the threshold voltage of the first transistor T1 from the voltage difference between the gate and the first electrode of the first transistor T1, and the light-emitting element LED may emit light with a luminance corresponding to the driving current.

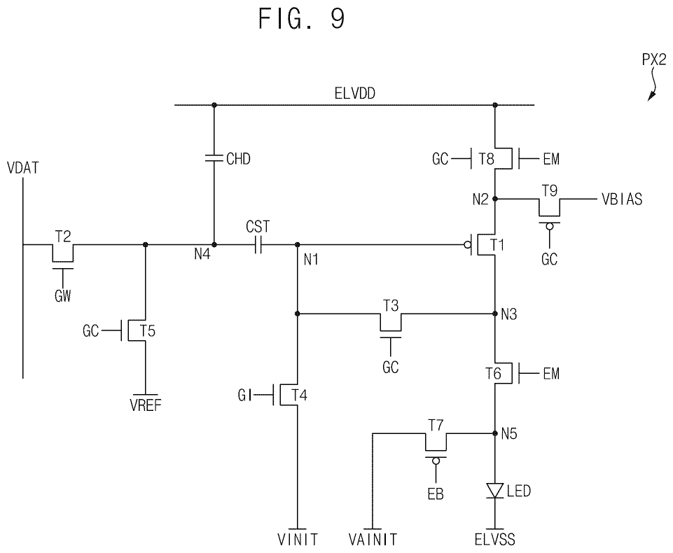

FIG. 9 is a schematic diagram of an equivalent circuit of an example of the pixel PX2 of FIG. 1.

Referring to FIG. 9, the pixel PX2 may receive the first gate signal GW, the second gate signal GC, the third gate signal GI, the first emission signal EM, the second emission signal EB, the data voltage VDAT, a first initialization voltage VINIT, a second initialization voltage VAINIT, a reference voltage VREF, a first power voltage ELVDD, a second power voltage ELVSS, and a bias voltage VBIAS. The pixel PX2 may include a light-emitting element LED, a first transistor T1, a second transistor T2, a third transistor T3, a fourth transistor T4, a fifth transistor T5, a sixth transistor T6, a seventh transistor T7, an eighth transistor (or emission control transistor) T8, a ninth transistor (or bias control transistor) T9, a storage capacitor CST, and a hold capacitor CHD.

Descriptions of components of the pixel PX2 described with reference to FIG. 9, which are substantially the same as or similar to those of the pixel PX1 described with reference to FIGS. 2 to 8, will be omitted.

The ninth transistor T9 may transmit the bias voltage VBIAS to the second node N2 in response to the second emission signal EB. The ninth transistor T9 may include a gate receiving the second emission signal EB, a first electrode receiving the bias voltage VBIAS, and a second electrode connected to the second node N2.

In an embodiment, each of the first, seventh, and ninth transistors T1, T7, and T9 may be a polysilicon PMOS transistor, and each of the second to seventh transistors T2, T3, T4, T5, T6, and T7 may be an oxide NMOS transistor. However, embodiments are not limited thereto, and in another embodiment, at least one of the seventh and ninth transistors T7 and T9 may be an oxide NMOS transistor.

Referring to FIGS. 3 and 9, in the bypass period PB, the ninth transistor T9 may be turned-on in response to the second emission signal EB having the activation level, and the bias voltage VBIAS may be applied to the second node N2 through the ninth transistor T9. Accordingly, hysteresis of the first transistor T1 may be alleviated, and a shift of the threshold voltage of the first transistor T1 may be reduced. In the display device 100 according to the present embodiment, the eighth transistor T8 of the pixel PX1 and PX2 may be turned-on in response to the second gate signal GC or the first emission signal EM, and thus, the number of signals provided to the pixel PX1 and PX2 may be reduced, and power consumption and a dead space of the display device 100 may be reduced.

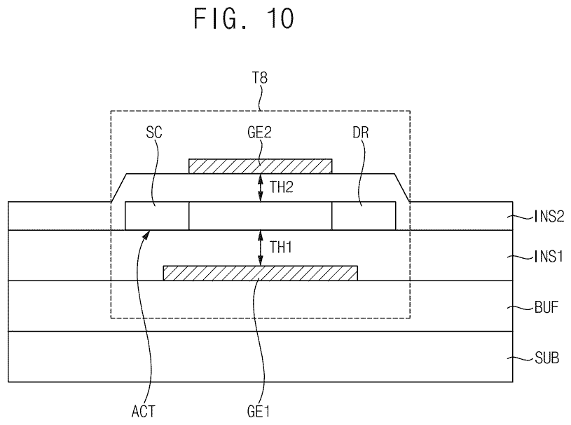

FIG. 10 is a schematic cross-sectional view showing an eighth transistor T8 of FIGS. 2 and 9.

Referring to FIG. 10, the display device may include a substrate SUB, a buffer layer BUF, a first gate electrode GE1, a first insulation layer INS1, an active layer ACT, a second insulation layer INS2, and a second gate electrode GE2. The eighth transistor T8 may be defined by the first gate electrode GE1, the first insulation layer INS1, the active layer ACT, the second insulation layer INS2, and the second gate electrode GE2.

The buffer layer BUF may be disposed on the substrate SUB. The buffer layer BUF may include a silicon compound such as silicon nitride, silicon oxide, silicon oxynitride, or the like.

The first gate electrode GE1 may be disposed on the buffer layer BUF. The first gate electrode GE1 may include a metal such as molybdenum (Mo), titanium (Ti), aluminum (Al), or the like. The first gate electrode GE1 may correspond to the second gate of the eighth transistor T8.

Although FIG. 10 illustrates that the buffer layer BUF is disposed between the substrate SUB and the first gate electrode GE1, embodiments are not limited thereto. In an embodiment, an additional insulation layer may be disposed between the substrate SUB and the first gate electrode GE1 in addition to the buffer layer BUF. In an embodiment, the buffer layer BUF may not be disposed between the substrate SUB and the first gate electrode GE1.

The first insulation layer INS1 may be disposed on the first gate electrode GE1. The first insulation layer INS1 may insulate the active layer ACT from the first gate electrode GE1. The first insulation layer INS1 may include a silicon compound such as silicon nitride, silicon oxide, silicon oxynitride, etc.

The active layer ACT may be disposed on the first insulation layer INS1, and may overlap the first gate electrode GE1. A source SC may be formed at a first end of the active layer ACT, and a drain DR may be formed at a second end of the active layer ACT opposite to the first end of the active layer ACT. The drain DR may correspond to a first electrode of the eighth transistor T8, and the source SC may correspond to a second electrode of the eighth transistor T8. The active layer ACT may include an oxide semiconductor. In an embodiment, the active layer ACT may include at least one oxide semiconductor of indium gallium zinc oxide (IGZO), indium tin gallium zinc oxide (ITGZO), and indium gallium Oxide (IGO). Accordingly, the active layer ACT may have a relatively high charge mobility.

The second insulation layer INS2 may be disposed on the active layer ACT. The second insulation layer INS2 may insulate the second gate electrode GE2 from the active layer ACT. The second insulation layer INS2 may include a silicon compound such as silicon nitride, silicon oxide, silicon oxynitride, etc.

The second gate electrode GE2 may be disposed on the second insulation layer INS2, and may overlap the active layer ACT. The second gate electrode GE2 may include a metal such as molybdenum (Mo), titanium (Ti), aluminum (Al), etc. The second gate electrode GE2 may correspond to the first gate of the eighth transistor T8.

A thickness ratio of the first insulation layer INS1 and the second insulation layer INS2 may be less than 2:1. In an embodiment, a thickness TH1 of the first insulation layer INS1 may be greater than a thickness TH2 of the second insulation layer INS2, and may be less than twice the thickness TH2 of the second insulation layer INS2.

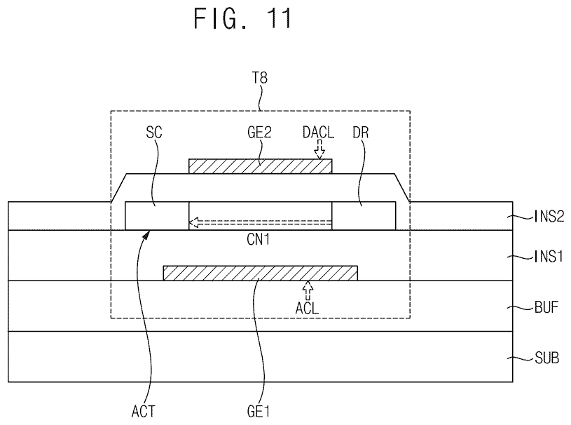

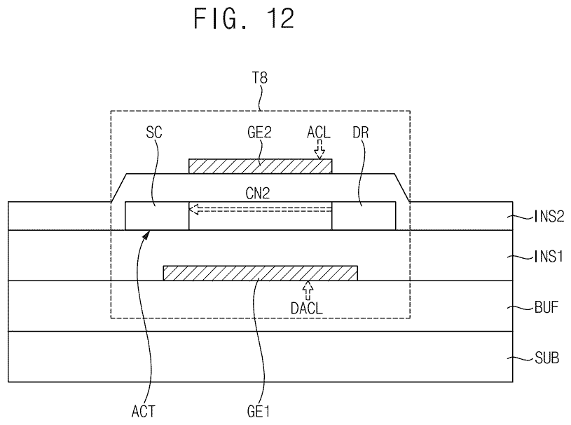

FIGS. 11 and 12 are schematic views for describing an operation of the eighth transistor T8 of FIG. 10.

Referring to FIGS. 11 and 12, the eighth transistor T8 may be turned-on in case that a signal having an activation level ACL is applied to the first gate electrode GE1 or in case that a signal having an activation level ACL is applied to the second gate electrode GE2. In case that the thickness ratio of the first insulation layer INS1 and the second insulation layer INS2 is less than 2:1 and the active layer ACT has a relatively high charge mobility, the eighth transistor T8 may be turned-on in response to the signal having the activation level ACL applied to either the first gate electrode GE1 or the second gate electrode GE2.

As illustrated in FIG. 11, in case that the signal having the activation level ACL is applied to the first gate electrode GE1 and a signal having a deactivation level DACL is applied to the second gate electrode GE2, a first channel CN1 may be formed in a direction from the drain DR to the source SC in a portion of the active layer ACT adjacent to the first insulation layer INS1. Accordingly, the eighth transistor T8 may be turned-on, and current may flow from the drain DR to the source SC through the first channel CN1.

As illustrated in FIG. 12, in case that the signal having the activation level ACL is applied to the second gate electrode GE2 and the signal having the deactivation level DACL is applied to the first gate electrode GE1, a second channel CN2 may be formed in a direction from the drain DR to the source SC in a portion of the active layer ACT adjacent to the second insulation layer INS2. Accordingly, the eighth transistor T8 may be turned-on, and current may flow from the drain DR to the source SC through the second channel CN2.

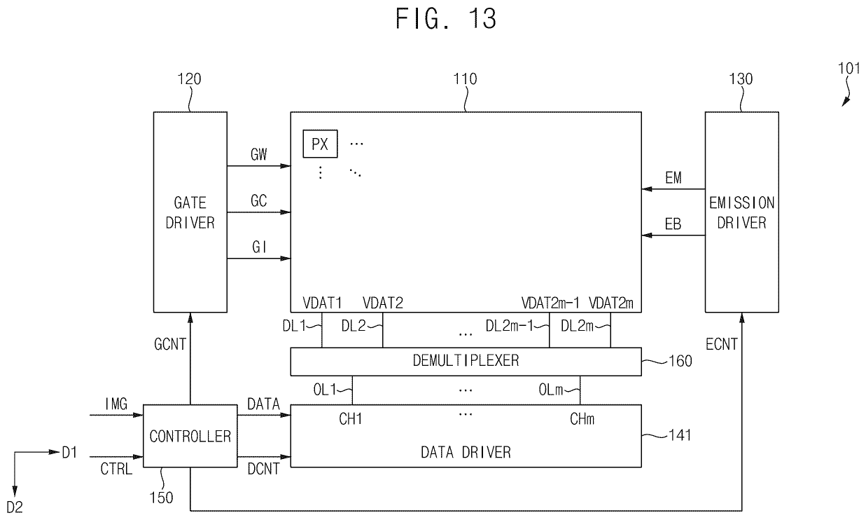

FIG. 13 is a schematic block diagram showing a display device 101 according to an embodiment.

Referring to FIG. 13, a display device 101 may include a display panel 110, a gate driver 120, an emission driver 130, a data driver 141, a demultiplexer 160, and a controller 150.

Descriptions of components of the display device 101 described with reference to FIG. 13, which are substantially the same as or similar to those of the display device 100 described with reference to FIG. 1, will be omitted.

The data driver 141 may output data voltages VDAT1, VDAT2, . . . , VDAT2m-1, and VDAT2m to output lines OL1, . . . , and OLm. The data driver 141 may include channels CH1, . . . , CHm that provide the data voltages VDAT1, VDAT2, . . . , VDAT2m-1, and VDAT2m to the data lines DL1, DL2, . . . , DL2m-1, and DL2m, respectively. The number of channels CH1, . . . , and CHm may be equal to the number of output lines OL1, . . . , and OLm, and may be less than the number of data lines DL1, DL2, . . . , DL2m-1, and DL2m. In an embodiment, the number of channels CH1, . . . , and CHm may be half of the number of data lines DL1, DL2, . . . , DL2m-1, and DL2m.

The demultiplexer 160 may selectively and electrically connect the channels CH1, . . . , and CHm to the data lines DL1, DL2, . . . , DL2m-1, and DL2m. The demultiplexer 160 may selectively connect the output lines OL1, . . . , and OLm respectively connected to the channels CH1, . . . , and CHm to the data lines DL1, DL2, . . . , DL2m-1, and DL2m. The demultiplexer 160 may selectively connect the channels CH1, . . . , and CHm to the data lines DL1, DL2, . . . , DL2m-1, and DL2m, and thus, the number of channels CH1, . . . , and CHm of the data driver 141 may be reduced, and power consumption and an area of the data driver 141 may be reduced.

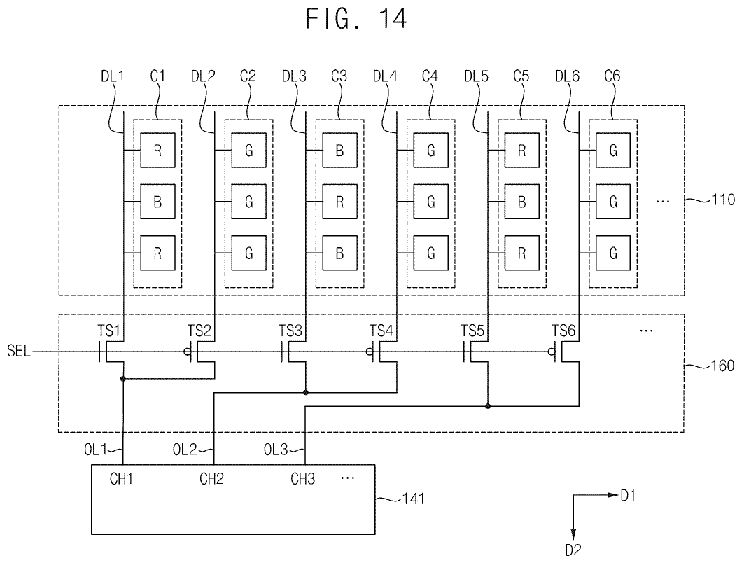

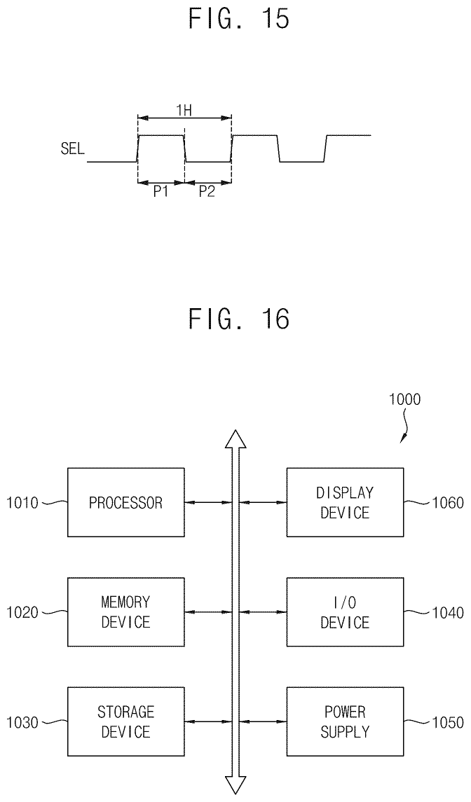

FIG. 14 is a schematic diagram of an equivalent circuit of an example of the demultiplexer 160 of FIG. 13. FIG. 15 is a timing diagram showing a selection signal SEL provided to the demultiplexer 160 of FIG. 14.

Referring to FIGS. 14 and 15, the display panel 110 may include pixel columns C1, C2, C3, C4, C5, C6, . . . , extending in the second direction D2 and arranged in the first direction D1. Each of the pixel columns C1, C2, C3, C4, C5, C6, . . . , may include pixels R, G, and B. The first pixel column C1 may be connected to the first data line DL1, and the second pixel column C2 may be connected to the second data line DL2. The first pixel column Cl and the second pixel column C2 may be adjacent in the first direction D1. In an embodiment, the first pixel column C1 may include red pixels R and blue pixels R that are alternately arranged in the second direction D2, and the second pixel column C2 may include green pixels G that are arranged in the second direction D2. The third and fifth pixel columns C3 and C5 are substantially the same as or similar to the first pixel column C1, and the fourth and sixth pixel columns C4 and C6 are substantially the same as or similar to the second pixel column C2, and thus, descriptions of the third to sixth pixel columns C3, C4, C5, and C6 will be omitted for descriptive convenience.

The demultiplexer 160 may selectively and electrically connect a first channel CH1 to first and second data lines DL1 and DL2, may selectively connect a second channel CH2 to third and fourth data lines DL3 and DL4, and may selectively connect a third channel CH3 to fifth and sixth data lines DL5 and DL6. The demultiplexer 160 may include selection transistors TS1, TS2, TS3, TS4, TS5, TS6, . . . , arranged in the first direction D1. The selection transistors TS1, TS2, TS3, TS4, TS5, TS6, . . . , may be turned-on in response to a selection signal SEL.

The first selection transistor TS1 may connect the first channel CH1 and the first data line DL1 in response to the selection signal SEL. The first selection transistor TS1 may include a gate receiving the selection signal SEL, a first electrode connected to the first output line OL1, and a second electrode connected to the first data line DL1.

The second selection transistor TS2 may connect the first channel CH1 and the second data line DL2 in response to the selection signal SEL. The second selection transistor TS2 may include a gate receiving the selection signal SEL, a first electrode connected to the first output line OL1, and a second electrode connected to the second data line DL2.

The first selection transistor TS1 may be a first type transistor, and the second selection transistor TS2 may be a second type transistor different from the first type transistor. In an embodiment, the first selection transistor TS1 may be an NMOS transistor, and the second selection transistor TS2 may be a PMOS transistor.

In an embodiment, the selection signal SEL may have a logic high level in a first period P1 of one horizontal period (1H), and may have a logic low level in a second period P2 of one horizontal period (1H) subsequent to the first period P1.

In the first period P1, in response to the selection signal SEL having the logic high level, the first selection transistor TS1 may be turned-on, and the second selection transistor TS2 may be turned-off. Accordingly, the first data voltage VDAT1 output from the first channel CH1 in the first period P1 may be provided to the first data line DL1 through the first selection transistor TS1.

In the second period P2, in response to the selection signal SEL having the logic low level, the first selection transistor TS1 may be turned-off, and the second selection transistor TS2 may be turned-on. Accordingly, the second data voltage VDAT2 output from the first channel CH1 in the second period P2 may be provided to the second data line DL2 through the second selection transistor TS2.

Since the third and fifth selection transistors TS3 and TS5 are substantially the same as or similar to the first selection transistor TS1 and the fourth and sixth selection transistors TS4 and TS6 are substantially the same as or similar to the second selection transistor TS2, description of the third to sixth selection transistors TS3, TS4, TS5, and TS6 will be omitted.

In the display device 101 according to the present embodiment, the selection transistors TS1, TS2, TS3, TS4, TS5, TS6, . . . , of the demultiplexer 160 may be turned-on in response to the selection signal SEL, and thus, the number of selection signals SEL may be reduced, and power consumption and a dead space of the display device 101 may be reduced.

FIG. 16 is a schematic block diagram showing an electronic apparatus 1000 according to an embodiment.

Referring to FIG. 16, the electronic apparatus 1000 may include a processor 1010, a memory device 1020, a storage device 1030, an input/output (I/O) device 1040, a power supply 1050, and a display device 1060. The electronic apparatus 1000 may further include ports capable of communicating with a video card, a sound card, a memory card, a USB device, and the like, or communicating with other systems. The electronic apparatus 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

The processor 1010 may perform specific calculations or tasks. According to an embodiment, the processor 1010 may be a microprocessor, a central processing unit (CPU), or the like. The processor 1010 may be connected to other components through an address bus, a control bus, a data bus, and the like. According to an embodiment, the processor 1010 may also be connected to an expansion bus such as a peripheral component interconnect (PCI) bus.

The processor 1010 may control the display device 1060. In an embodiment, the processor 1010 may generate the image data IMG of FIGS. 1 and 13, and the controller control signal CTRL of FIGS. 1 and 13, and may provide the image data IMG and the controller control signal CTRL to the display device 1060.

The memory device 1020 may store data required for an operation of the electronic apparatus 1000. For example, the memory device 1020 may include: a nonvolatile memory device such as an erasable programmable read-only memory (EPROM), an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), or a ferroelectric random access memory (FRAM); and/or a volatile memory device such as a dynamic random access memory (DRAM), a static random access memory (SRAM), or a mobile DRAM.

The storage device 1030 may include a solid state drive (SSD), a hard disk drive (HDD), a CD-ROM, and the like. The I/O device 1040 may include: an input device such as a keyboard, a keypad, a touch pad, a touch screen, or a mouse; and an output device such as a speaker or a printer. The power supply 1050 may supply a power required for the operation of the electronic apparatus 1000. The display device 1060 may be connected to other components through the buses or other communication links. The display device 1060 may correspond to the display device 100 of FIG. 1 or the display device 101 of FIG. 13.

In the display device 1060, an eighth transistor of a pixel may be turned-on in response to a second gate signal or a first emission signal, and thus, the number of signals provided to the pixel may be reduced, and power consumption and a dead space of the display device 1060 may be reduced. Further, first and second selection transistors of a demultiplexer may be turned-on in response to a selection signal, and thus, the number of selection signals may be reduced, and the power consumption and the dead space of the display device may be reduced.

The display device according to the embodiments may be applied to a display device included in a computer, a notebook, a mobile phone, a smart phone, a smart pad, a smart watch, a PMP, a PDA, an MP3 player, or the like.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a pixel comprising:
a light-emitting element;
a first transistor which controls a driving current flowing through the light-emitting element, and including a gate connected to a first node, a first electrode connected to a second node, and a second electrode connected to a third node;
a second transistor which transmits a data voltage to a fourth node in response to a first gate signal;
a storage capacitor connected between the first node and the fourth node; and
an emission control transistor which transmits a first power voltage to the second node in response to a second gate signal or a first emission signal, including a first gate which receives the first emission signal and a second gate which receives the second gate signal, and being an oxide n-channel metal oxide semiconductor (NMOS) transistor.

2. The display device of claim 1, wherein the pixel further comprises:
a third transistor which connects the first node and the third node in response to the second gate signal;
a fourth transistor which transmits a first initialization voltage to the first node in response to a third gate signal; and
a fifth transistor which transmits a reference voltage to the fourth node in response to the second gate signal.

3. The display device of claim 2, wherein, in a compensation period, the emission control transistor is turned-on in response to the second gate signal having an activation level, and the first power voltage for which a threshold voltage of the first transistor is compensated is applied to the first node through the emission control transistor, the first transistor, and the third transistor.

4. The display device of claim 2, wherein the pixel further comprises:
a sixth transistor which connects the third node and an anode of the light-emitting element in response to the first emission signal; and
a seventh transistor which transmits a second initialization voltage to the anode of the light-emitting element in response to a second emission signal.

5. The display device of claim 4, wherein, in an emission period, the emission control transistor is turned-on in response to the first emission signal having an activation level, and a path of the driving current is formed through the emission control transistor, the first transistor, and the sixth transistor.

6. The display device of claim 4, wherein each of the first to seventh transistors is an oxide NMOS transistor.

7. The display device of claim 4, wherein the pixel further comprises:
a hold capacitor including a first electrode connected to the fourth node and a second electrode which receives the first power voltage.

8. The display device of claim 4, wherein the pixel further comprises:
a bias control transistor which provides a bias voltage to the second node in response to the second emission signal.

9. The display device of claim 8, wherein the first transistor is a polysilicon p-channel metal oxide semiconductor (PMOS) transistor, and
wherein each of the second to sixth transistors is an oxide NMOS transistor.

10. The display device of claim 8, wherein each of the seventh transistor and the bias control transistor is a polysilicon PMOS transistor.

11. A display device comprising:
a substrate;
a first gate electrode disposed on the substrate;
a first insulation layer disposed on the first gate electrode;
an active layer disposed on the first insulation layer, overlapping the first gate electrode, and including an oxide semiconductor;
a second insulation layer disposed on the active layer; and
a second gate electrode disposed on the second insulation layer and overlapping the active layer,
wherein a thickness ratio of the first insulation layer and the second insulation layer is less than 2:1.

12. The display device of claim 11, wherein a thickness of the first insulation layer is greater than a thickness of the second insulation layer and less than twice the thickness of the second insulation layer.

13. The display device of claim 11, wherein, in case that a signal having an activation level is applied to the first gate electrode and a signal having a deactivation level is applied to the second gate electrode, a first channel is formed in a direction from a drain of the active layer toward a source of the active layer in a portion of the active layer adjacent to the first insulation layer.

14. The display device of claim 13, wherein, in case that a signal having an activation level is applied to the second gate electrode and a signal having a deactivation level is applied to the first gate electrode, a second channel is formed in a direction from the drain toward the source in a portion of the active layer adjacent to the second insulation layer.

15. The display device of claim 11, wherein the active layer includes at least one oxide semiconductor of indium gallium zinc oxide (IGZO), indium tin gallium zinc oxide (ITGZO), and indium gallium oxide (IGO).

16. An electronic apparatus comprising:
a display device comprising:
a pixel; and
a processor which controls the display device, the pixel comprising:
a light-emitting element;
a first transistor which controls a driving current flowing through the light-emitting element and including a gate connected to a first node, a first electrode connected to a second node, and a second electrode connected to a third node;
a second transistor which transmits a data voltage to a fourth node in response to a first gate signal;
a storage capacitor connected between the first node and the fourth node; and
an emission control transistor which transmits a first power voltage to the second node in response to a second gate signal or a first emission signal, including a first gate which receives the first emission signal and a second gate which receives the second gate signal, and being an oxide NMOS transistor.

17. The electronic apparatus of claim 16, wherein the pixel further comprises:
a third transistor which connects the first node and the third node in response to the second gate signal;
a fourth transistor which transmits a first initialization voltage to the first node in response to a third gate signal; and
a fifth transistor which transmits a reference voltage to the fourth node in response to the second gate signal.

18. The electronic apparatus of claim 17, wherein, in a compensation period, the emission control transistor is turned-on in response to the second gate signal having an activation level, and the first power voltage for which a threshold voltage of the first transistor is compensated is applied to the first node through the emission control transistor, the first transistor, and the third transistor.

19. The electronic apparatus of claim 17, wherein the pixel further comprises:
a sixth transistor which connects the third node and an anode of the light-emitting element in response to the first emission signal; and
a seventh transistor which transmits a second initialization voltage to the anode of the light-emitting element in response to a second emission signal.

20. The electronic apparatus of claim 19, wherein, in an emission period, the emission control transistor is turned-on in response to the first emission signal having an activation level, and a path of the driving current is formed through the emission control transistor, the first transistor, and the sixth transistor.
